(19) United States
(12) Patent Application Publication
(10) Pub. No.: US 2026/0040895 A1
(43) Pub. Date: Feb. 5, 2026

(54) BONDING STRENGTH EVALUATION METHOD, BONDING STRENGTH EVALUATION DEVICE, AND DRIVING METHOD THEREOF

(71) Applicant: SK hynix Inc., Gyeonggi-do (KR)

(72) Inventors: Heon Yong CHANG, Gyeonggi-do (KR); Young Hun CHEONG, Gyeonggi-do (KR)

(21) Appl. No.: 19/187,998

(22) Filed: Apr. 24, 2025

(30) Foreign Application Priority Data
Aug. 1, 2024 (KR) 10-2024-0102604
Dec. 23, 2024 (KR) 10-2024-0193598

(51) Int. Cl. H01L 21/66; G01N 19/04

(52) U.S. Cl. CPC H01L 22/12; G01N 19/04

(57) ABSTRACT

A bonding strength evaluation method may include preparing bonded wafers, separating the bonded wafers by applying a force to one surface of the bonded wafers in a direction perpendicular to the one surface of the bonded wafers, measuring at least one of the force applied to the one surface of the bonded wafers, a time when the force is applied, a separation distance between the bonded wafers, a length of an area where the bonded wafers are separated, and determining a bonding strength based on at least one of the force, the time during which the force is applied, the separation distance between the bonded wafers, and the length of the area where the bonded wafers are separated.

### CROSS-REFERENCES TO RELATED APPLICATION

The present application claims priority under 35 U.S.C. 119(a) to Korean patent application number 10-2024-0102604 filed on Aug. 1, 2024, and Korean patent application number 10-2024-0193598 filed on Dec. 23, 2024, which are incorporated herein by reference in their entirety.

### TECHNICAL FIELD

Embodiments of the present disclosure relate to a bonding strength evaluation method, a bonding strength evaluation device, and a driving method thereof.

### BACKGROUND

As semiconductor devices become more highly integrated, wafer bonding processes are being introduced. However, if the bonding strength at the bonding interface of the bonded wafers, i.e., the wafer bonding strength, is not sufficient, defects may occur in the bonded wafers in various processes performed after the wafer bonding process. Since defects in bonded wafers reduce manufacturing yield, it is necessary to measure and manage wafer bonding strength.

There are various known methods for measuring wafer bonding strength. Among them, in wide use are the Maszara Test, which measures the crack length that occurs when separating a bonded wafer with a blade and determines the bonding strength therefrom, or the double cantilever beam (DCB) test, which measures the bonding strength based on the separated distance of the bonding interface while repeatedly applying and removing force to/from the bonded wafer.

However, the Maszara test suffers from decreased accuracy and precision due to many factors that affect the wafer bonding strength since the measurement is performed at a certain point in time during which the debonding wave spreads after the edges of the bonded wafer are separated. The DCB test also has decreased accuracy due to stress-induced corrosion and other effects as stress is repeatedly applied to the wafer.

### SUMMARY

Embodiments of the present disclosure provide a bonding strength evaluation method, a bonding strength evaluation device, and a driving method thereof, which may enhance the accuracy of bonding strength evaluation.

Embodiments of the present disclosure may provide a bonding strength evaluation method which may include preparing bonded wafers, separating the bonded wafers by applying a force to one surface of the bonded wafers in a direction perpendicular to the one surface of the bonded wafers, measuring at least one of the force applied to the one surface of the bonded wafers, a time during which the force is applied, a separation distance between the bonded wafers, and a length of an area where the bonded wafers are separated, and determining a bonding strength based on at least one of the force, the time during which the force is applied, the separation distance between the bonded wafers, and the length of the area where the bonded wafers are separated.

Embodiments of the present disclosure may provide a bonding strength evaluation device including a wafer holder configured to fix bonded wafers, and a determination module configured to determine a bonding strength of the bonded wafers. The determination module includes a driver configured to separate the bonded wafers by applying a force to the bonded wafers in a direction perpendicular to one surface of the bonded wafers, and a sensor configured to measure at least one of the force applied to the one surface of the bonded wafers, a time during which the force is applied, a separation distance between the bonded wafers, and a length of an area where the bonded wafers are separated.

Embodiments of the present disclosure may provide a driving method of a bonding strength evaluation device, including fixing bonded wafers to a wafer holder and separating the bonded wafers by applying a force to one of the bonded wafers in a direction perpendicular to one surface of the one wafer while measuring at least one of the force applied to the one wafer, a time during which the force is applied, a separation distance between the bonded wafers, and a length of an area where the bonded wafers are separated, to determine a bonding strength.

According to embodiments of the present disclosure, the accuracy of a bonding strength evaluation method may be enhanced.

### BRIEF DESCRIPTION OF THE DRAWINGS

FIG. 1 is a flowchart illustrating a bonding strength evaluation method according to embodiments of the present disclosure;

FIG. 2 is a view illustrating implementing the separation operation of FIG. 1;

FIG. 3 is a view illustrating the separation operation of FIG. 1;

FIG. 4 is a view illustrating a bonding strength evaluation device according to embodiments of the present disclosure;

FIGS. 5 to 8 are views illustrating a driving method of a bonding strength evaluation device according to embodiments of the present disclosure; and

FIG. 9 is a view illustrating data measured when driving a bonding strength evaluation device according to embodiments of the present disclosure.

### DETAIL DESCRIPTION

Hereinafter, embodiments of the present disclosure are described in detail with reference to the accompanying drawings. In assigning reference numerals to components of each drawing, the same components may be assigned the same numerals even when they are shown on different drawings. When it is determined that the subject matter of the present disclosure will be unclear, the details of the known art or functions may be skipped. As used herein, when a component “includes,” “has,” or “is composed of” another component, the component may add other components unless the term “only” is used with “includes, has, or is composed of” the other component. As used herein, the singular forms “a”, “an” and “the” are intended to include the plural forms as well, unless the context clearly indicates otherwise.

Such labels as “first,” “second,” “A,” “B,” “(a),” and “(b),” may be used in describing the components of the embodiments of the present disclosure. These labels are provided merely to distinguish a component from another, and the essence, order, or number of the components are not limited by the labels.

In describing the positional relationship between components, when two or more components are described as “connected”, “coupled” or “linked”, the two or more components may be directly “connected”, “coupled” or “linked””, or another component may intervene. Here, the other component may be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, the temporal flow relationship may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

Hereinafter, various embodiments of the present disclosure will be described in detail with reference to accompanying drawings.

In the accompanying drawings, the two directions parallel to the upper surface of the wafer are defined as a first direction FD and a second direction SD, respectively, and the direction protruding vertically from the upper surface of the wafer is defined as a third direction VD. The first direction FD and the second direction SD may be substantially perpendicular to each other. The third direction VD is a direction perpendicular to the first direction FD and the second direction SD. In the following specification, ‘vertical’ or ‘vertical direction’ will be used as having substantially the same meaning as the third direction VD. The direction indicated by arrow in the drawings and the opposite direction indicate the same direction.

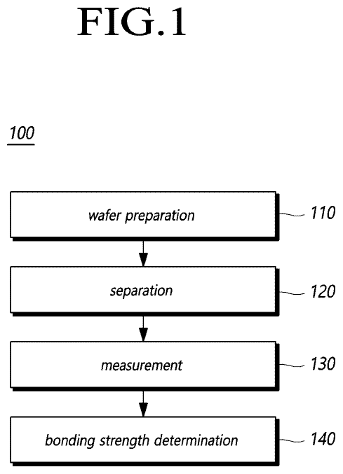

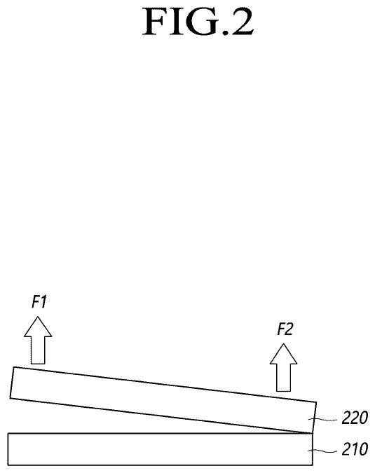

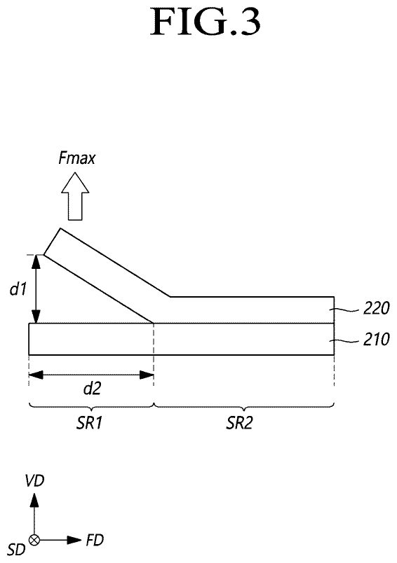

FIG. 1 is a flowchart illustrating a bonding strength evaluation method 100 according to embodiments of the present disclosure. FIG. 2 is a view illustrating implementing a separation operation of FIG. 1. FIG. 3 is a view illustrating the separation operation of FIG. 1.

Referring to FIG. 1, the bonding strength evaluation method 100 may include a wafer preparation operation 110, a separation operation 120, a measurement operation 130, and a bonding strength determination operation 140.

In the wafer preparation operation 110, bonded wafers are prepared. Each of the wafers may include a wafer body and integrated circuits disposed on the wafer body. The wafer body may include silicon or a semiconductor such as a silicon on insulator (SOI). The wafer body may include a group III-V semiconductor, e.g., a compound semiconductor such as GaAs. The wafer body may include mono-crystalline silicon, polysilicon, amorphous silicon, mono-crystalline silicon germanium, poly-crystalline silicon germanium, carbon-doped silicon, or a combination thereof. The integrated circuits may be formed through a front end of line (FEOL) process and a back end of line (BEOL) process in an embodiment.

In an embodiment, the bonded wafers may include a cell wafer on which memory cells of a memory device are disposed and a peri wafer on which a peripheral circuit for transmitting various signals and voltages to the memory cells is disposed to drive the memory cells. The bonded wafers may be wafers in which the cell wafer and the peri wafer are bonded through a hybrid bonding process.

In an embodiment, the bonded wafers may include only the cell wafer. In this case, one cell wafer is bonded to another cell wafer to form the bonded wafers. A structure in which memory cells are vertically stacked may be implemented through the bonded wafers.

In the separation operation 120, a force may be applied to one surface of the bonded wafers to separate the bonded wafers. The force may be applied in a direction perpendicular to the one surface of the bonded wafers. In an embodiment, the force may be a tension that pulls the bonded wafers in the direction perpendicular to the one surface of the wafer.

Referring to FIG. 2, in a state in which a first wafer 210 among the bonded wafers 210 and 220 is fixed, a force may be applied to only one surface of the second wafer 220 to separate the bonded wafers 210 and 220 from each other.

In an embodiment, in order to fix the first wafer 210, a device for placing the first wafer 210 on a fixing table and vacuuming the space between the first wafer 210 and the fixing table may be used. However, without limitations thereto, the first wafer 210 may be fixed in various ways.

In an embodiment, in order to apply a force to the second wafer 220, a driving device that provides a force for pulling the second wafer 220 upward while contacting the upper surface of the second wafer 220 may be used. The driving device may apply a force to the second wafer 220 while moving in a direction perpendicular to the upper surface of the wafer while maintaining a space between the driving device and the second wafer 220 in a vacuum while contacting the upper surface of the second wafer 220. However, without limitations thereto, various methods capable of applying a force in a direction perpendicular to one surface of the second wafer 220 may be used.

A force may be applied from the edge of one surface of the second wafer 220 to separate the bonded wafers 210 and 220.

In an embodiment, a first force F1 and a second force F2 may be applied to one surface of the second wafer 220. The first force F1 may first act on one edge of the second wafer 220 to pull the second wafer 220 in the vertical direction. If the second wafer 220 starts being separated from the first wafer 210 by the first force F1, a second force F2 may be applied. The second force F2 may act on the other edge of the second wafer 220 to pull the second wafer 220 in the vertical direction. The second wafer 220 may be completely separated from the first wafer 210 by the first force F1 and the second force F2.

The first force F1 and the second force F2 may be provided from any driving device, and the first force F1 and the second force F2 may be provided independently of each other.

For convenience of description, FIG. 2 illustrates that force is applied only to one side and the other side of the edge of the second wafer 220, but is not limited thereto, and various methods may be used to separate the bonded wafers 210 and 220 from one edge. For example, a force may be sequentially applied to one side of the edge of the second wafer 220, the center of the second wafer 220, and the other side of the edge of the second wafer 220.

Referring to FIG. 3, only some of the bonded wafers 210 and 220 may be separated in the separation operation 120. As shown in FIG. 2, since a force is applied to separate the bonded wafers 210 and 220 from the edge of one surface of the bonded wafers 210 and 220, some of the bonded wafers 210 and 220 may be separated and others may remain bonded at a specific moment in the separation operation 120.

For example, the first wafer 210 may include an area SR2 bonded to the second wafer 220 and an area SR1 separated from the second wafer 220 at the moment when the maximum force Fmax is applied to the second wafer 220 in the separation operation 120.

The separation distance d1 between the bonded wafers 210 and 220 may be defined as a maximum distance in a vertical direction from the edge of one surface of the second wafer 220 to the upper surface of the first wafer 210 when the maximum force is applied to the bonded wafers 210 and 220. Further, the length d2 of the area where the bonded wafers 210 and 220 are separated may be defined as a maximum distance from the edge of the first wafer 210 to the area SR2 where the bonded wafers 210 and 220 are bonded when the maximum force is applied to the bonded wafers 210 and 220.

In the measurement operation 130, the force applied to one surface of the bonded wafers or the time during which the force is applied is measured. The force may be the first force F1 applied to the second wafer 220 as described above with reference to FIG. 2.

Further, in the measurement operation 130, the separation distance between the bonded wafers or the length of the area where the bonded wafers are separated is measured.

In an embodiment, in the measurement operation 130, at least one of the force applied to one surface of the bonded wafers, the time during which the force is applied, the separation distance between the bonded wafers, or the length of the area where the bonded wafers are separated is measured.

The force applied to one surface of the bonded wafers and the time during which the force is applied are measured from the moment when the force is applied to the wafer to the moment when the bonded wafers are completely separated.

In the bonding strength determination operation 140, a bonding strength is determined based on the force applied to one surface of the bonded wafers or the time during which the force is applied.

Further, in the bonding strength determination operation 140, the bonding strength is determined based on the separation distance between the bonded wafers or the length of the area where the bonded wafers are separated.

In an embodiment, in the bonding strength determination operation 140, the bonding strength is determined based on the force applied to one surface of the bonded wafers, the time during which the force is applied to one surface of the bonded wafers, the separation distance between the bonded wafers, the length of the area where the bonded wafers are separated, or a combination thereof.

In an embodiment, when the bonding strength is determined based on the force applied to one surface of the bonded wafers, the bonding strength may be determined as the maximum force among forces applied to one surface of the bonded wafers. Since the maximum force among the forces applied to one surface of the bonded wafers is directly measured in the measurement operation 130, the bonding strength of the bonded wafers may be directly measured as a numerical value. That is, when there are wafers bonded in different ways, the bonding strength may be absolutely evaluated by measuring the maximum force applied to one surface of the bonded wafers.

Alternatively, in one configuration, when determining the bonding strength based on the time during which the force is applied to one surface of the bonded wafers, the bonding strength may be determined based on the time during which the maximum force is maintained among the forces applied to one surface of the bonded wafers.

As described above, in the separation operation 120, the bonded wafers start being separated from the edge. In general, wafers are manufactured in a circular shape, so when a wafer is separated from the edge of the wafer, the bonding area is small at the moment when the separation starts, so bonded wafers may be separated with a relatively small force. As the bonded wafers are separated, the bonding area increases as the area where separation occurs approaches the center of the wafer, so greater force is required to separate the bonded wafers. When the area where separation occurs passes through the center of the wafer, the bonding area decreases again, so the force required to separate the bonded wafers decreases.

As the time during which the maximum force among the forces applied to one surface of the bonded wafers is maintained increases, the bonding strength of the bonded wafers increases. Therefore, if there are wafers bonded in different ways, the bonding strength of the bonded wafers may be evaluated relatively by measuring the time during which the maximum force applied to one surface of the bonded wafers is maintained. In an embodiment, when the bonding strength is evaluated based on the time during which the maximum force is maintained, the bonding strength is evaluated based on the area having the largest bonding area. Thus, the bonding strength evaluated by the above method may best represent the total bonding strength of the bonded wafer. Further, the measurement time may be shortened because it is not necessary to measure the time taken to completely separate the bonded wafer.

In an embodiment, when determining the bonding strength based on the time during which force is applied to one surface of the bonded wafers, the bonding strength may be determined based on the time taken from the moment when force is applied to the bonded wafers to the moment when the bonded wafers are completely separated, or the time taken from the moment when the bonded wafers start being separated to the moment when the bonded wafers are completely separated.

The bonding strength of bonded wafers increases as the time taken from the moment when the force is applied to the bonded wafers to the moment when the bonded wafers are completely separated or the time taken from the bonded wafers start being separated to the moment when the bonded wafers are completely separated increases. Therefore, when there are wafers bonded in different ways, the bonding strength of bonded wafers may be evaluated relatively by measuring the time taken from the moment when the force is applied to the bonded wafers to the moment when the bonded wafers are completely separated or the time taken from the moment when the bonded wafers start being separated to the moment when the bonded wafers are completely separated.

In an embodiment, when the bonding strength is evaluated based on the time taken from the moment when the force is applied to the bonded wafers to the moment when the bonded wafers are completely separated or the time taken from the moment when the bonded wafers start being separated to the moment when the bonded wafers are completely separated, the bonding strength is evaluated based on the bonding strength of the entire area of the bonded wafer, so that the bonding strength of the bonded wafers may be measured most accurately.

In an embodiment, when the bonding strength is determined based on the time during which the force is applied to one surface of the bonded wafers, the bonding strength may be determined based on the product of the maximum force among the forces applied to one surface of the bonded wafers and the time during which the maximum force is maintained.

As described above, as the maximum force among the forces applied to one surface of the bonded wafers increases, and as the time during which the maximum force is maintained increases, the bonding strength of the bonded wafers increases. Therefore, when there are wafers bonded in different ways, the bonding strength of the bonded wafers may be evaluated relatively by measuring the maximum force among the forces applied to one surface of the bonded wafers and the time during which the maximum force is maintained. In an embodiment, since both the force and time applied are considered in determining the bonding strength of the bonded wafers, the bonding strength of the bonded wafers may be more accurately evaluated.

In an embodiment, when the bonding strength is determined based on the separation distance between the bonded wafers, the bonding strength may be determined based on the separation distance between the bonded wafers when the force applied to one surface of the bonded wafers is maximum.

When the force applied to one surface of the bonded wafers is maximum, as the separation distance between the bonded wafers decreases, the bonding strength of the wafers increases. Therefore, it is possible to evaluate the bonding strength between the wafers by measuring the separation distance between the bonded wafers at the moment when the force applied to one surface of the bonded wafers is maximum.

In an embodiment, when the bonding strength is determined based on the length of the area where the bonded wafers are separated, the bonding strength may be determined based on the length of the area where the bonded wafers are separated when the force applied to one surface of the bonded wafers is maximum.

As described above, when the force applied to one surface of the bonded wafers is maximum, as the length of the area where the bonded wafers are separated decreases, the bonding strength of the wafers increases. Therefore, the bonding strength may be determined based on the length of the area where the bonded wafers are separated at the moment when the force applied to one surface of the bonded wafers is maximum.

In an embodiment, when the bonding strength is determined based on the product of the separation distance between the bonded wafers and the length of the area where the bonded wafers are separated, the bonding strength may be determined based on the product of the separation distance between the bonded wafers and the length of the area where the bonded wafers are separated when the force applied to one surface of the bonded wafers is maximum.

Although the method for evaluating the bonding strength of bonded wafers has been described above, the above-described bonding strength evaluation method 100 may be used to evaluate not only bonding strength between bonded wafers, but also bonding strength between memory chip and wafer or bonding strength between memory chips. Further, the above-described bonding strength evaluation method 100 may also be used to evaluate the bonding strength of materials bonded by various bonding processes used in the process of manufacturing memory devices.

Hereinafter, a device implementing the above-described bonding strength evaluation method 100 and a driving method thereof are described as an example.

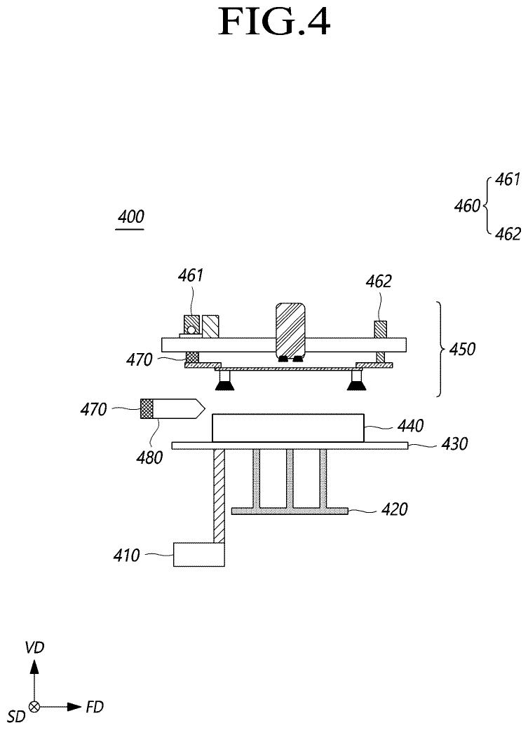

FIG. 4 is a view illustrating a bonding strength evaluation device 400 according to embodiments of the present disclosure.

Referring to FIG. 4, the bonding strength evaluation device 400 may include a motor 410, a first supporter 420, a second supporter 430, a wafer holder 440, a determination module 450, and a blade 480.

The motor 410 may control a vertical movement of the first supporter 420 and the second supporter 430. The first supporter 420 may move upward by passing through the wafer holder 440 in the vertical direction, and may be a reference for setting the position of the wafer on a plane defined in the first direction FD and the second direction SD. The second supporter 430 may serve to support the wafer holder 440.

Bonded wafers may be loaded on the wafer holder 440. The wafer fixing portion 440 may fix the bonded wafers. In an embodiment, in order to fix the bonded wafers on the wafer holder 440, a space between the wafer holder 440 and the bonded wafers may be made into a vacuum.

The determination module 450 may include a driver 460 and a sensor 470.

The driver 460 may apply a force in a direction perpendicular to the bonded wafers to separate the bonded wafers. The driver 460 may include a first driver 461 and a second driver 462. Each of the first driver 461 and the second driver 462 may contact an upper surface of one of the bonded wafers to apply a force to the upper surface of the one wafer. In an embodiment, the first driver 461 and the second driver 462 may contact one edge and the other edge, respectively, of the upper surface of the one wafer. In an embodiment, the force applied to the upper surface of the one wafer may be a tension that pulls the one wafer upward.

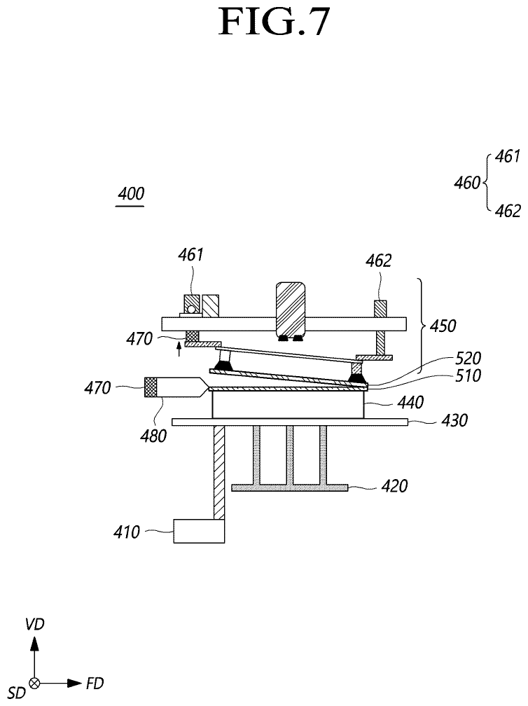

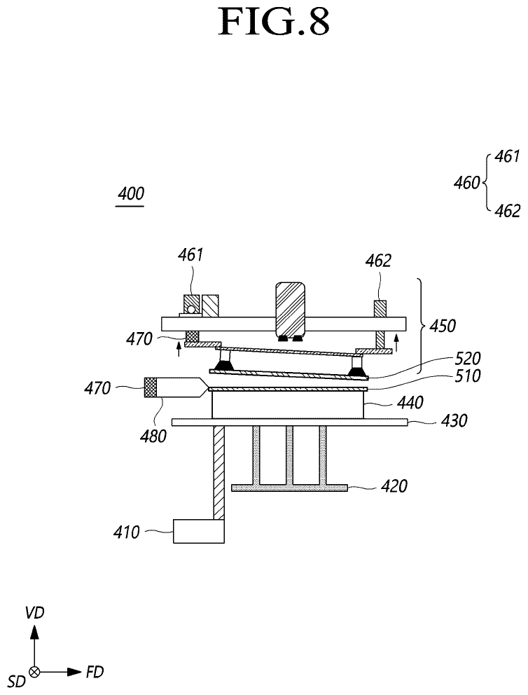

In an embodiment, the first driver 461 and the second driver 462 may be independently driven. For example, only the first driver 461 may apply a force to the upper surface of the one wafer before the bonded wafers are separated after the first driver 461 and the second driver 462 contact the upper surface of the one wafer. After the bonded wafers are separated, both the first driver 461 and the second driver 462 may apply a force to the upper surface of the one wafer. A detailed driving method of the first driver 461 and the second driver 462 is described below with reference to FIGS. 7 and 8.

The sensor 470 may be attached to the first driver 461 and the blade 480. The sensor 470 may measure the force applied by the first driver 461 to the one wafer and the time during which the force is applied. The sensor 470 may measure the force applied to one wafer and the time during which the force is applied in a period from the moment when the first driver 461 applies the force to the one wafer to the moment when the bonded wafers are completely separated.

The sensor 470 may also measure the separation distance between the bonded wafers 210 and 220 and the length of the area where the bonded wafers 210 and 220 are separated. The sensor 470 may measure the separation distance between the bonded wafers 210 and 220 and the length of the area where the bonded wafers 210 and 220 are separated when the force applied by the first driver 461 to one wafer is maximum.

In an embodiment, the sensor 470 may measure at least one of the force applied to one wafer, the time during which the force is applied, the separation distance between the bonded wafers 210 and 220, or the length of the area where the bonded wafers 210 and 220 are separated.

The blade 480 may be connected to a support table included in the bonding strength measurement device 100 or positioned outside the bonding strength measurement device 100. The blade 480 may be inserted between the bonding interfaces of the bonded wafers to apply a force to the bonding interfaces to separate the bonded wafers. The blade 480 may be a separate component from the determination module 450. Although FIG. 3 illustrates that the bonding strength evaluation device 400 may include the blade 480, the embodiment is not limited thereto, and the bonding strength evaluation device 400 may not include the blade 480.

The determination module 450 may determine the bonding strength of the bonded wafers based on the result measured by the sensor 470.

In an embodiment, the determination module 450 may determine the bonding strength of bonded wafers based on the force applied to one wafer, the time to apply a force to one wafer, the separation distance between bonded wafers, the length of the area where the bonded wafers are separated, or a combination thereof.

In an embodiment, if the force applied by the first driving unit 461 to the one wafer is measured by the sensor 470, the determination module 450 may determine the maximum force among the forces as the bonding strength.

In an embodiment, if the force applied to the one wafer by the first driver 461 is measured by the sensor 470, the determination module 450 may determine the bonding strength based on the time during which the maximum force among the forces is maintained, the time taken from the moment when the force is applied to the one wafer to the moment when the bonded wafers are completely separated, or the time taken from the moment when the bonded wafers start being separated to the moment when the bonded wafers are completely separated.

In an embodiment, when the force applied to the one wafer and the time during which the force is applied are measured by the sensor 470, the determination module 450 may determine the bonding strength based on the product of the maximum force among the forces applied to one surface of the one wafer and the time during which the maximum force is maintained.

In an embodiment, when the sensor 470 may measure the separation distance between the bonded wafers and the length of the area where the bonded wafers are separated, the determination module 450 may determine the bonding strength based on the separation distance between the bonded wafers or the length of the area where the bonded wafers are separated when the maximum force is applied to one surface of one wafer. For example, the determination module 450 may determine bonding strength based on the product of the separation distance between bonded wafers and the length of the area where the bonded wafers are separated when the maximum force is applied to one surface of a wafer.

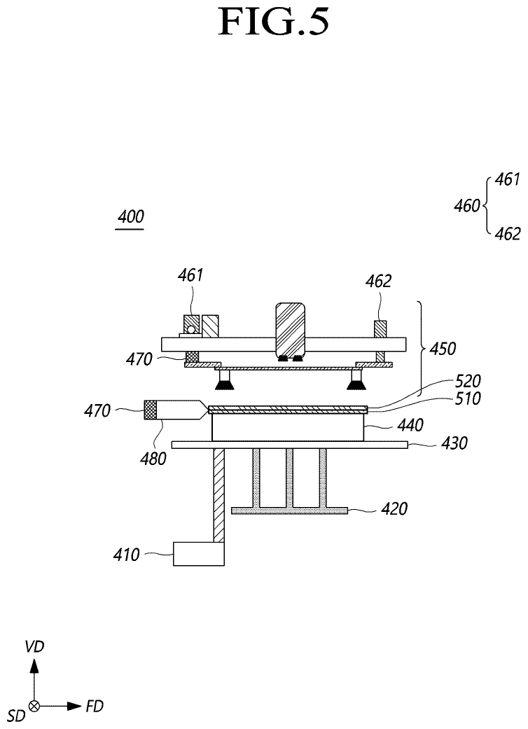

FIGS. 5 to 8 are views illustrating a driving method of a bonding strength evaluation device according to embodiments of the present disclosure.

Referring to FIG. 5, bonded wafers 510 and 520 may be loaded on the wafer holder 440. The bonded wafers 510 and 520 may be the same wafers as the bonded wafers 210 and 220 described with reference to FIGS. 1 and 2.

The bonded wafers 510 and 520 may be fixed on the wafer holder 440. In an embodiment, the bonded wafers 510 and 520 may be fixed on the wafer holder 440 by vacuuming a space between the bonded wafers 510 and 520 and the wafer holder 440.

After the bonded wafers 510 and 520 are fixed, the blade 480 may be inserted to the interface of the bonded wafers 510 and 520. In an embodiment, a process in which the blade 480 is inserted to the interface of the bonded wafers 510 and 520 may be omitted.

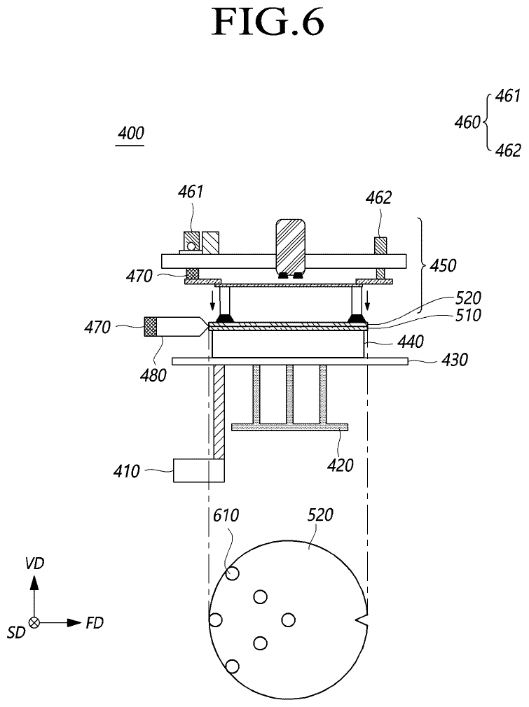

Referring to FIG. 6, the first driver 461 and the second driver 462 may be moved downward to contact the upper surface of the second wafer 520. The first driver 461 and the second driver 462 may contact the upper surface of the second wafer 520 at different positions, respectively. The first driver 461 may contact at least one of the first positions 610 on the second wafer 520. The first positions 610 shown in FIG. 5 are illustrative, and the position at which the first driver 461 contacts the second wafer 520 is not necessarily limited thereto. The second driver 462 contacts a position except for the first positions 610 of the edge of the upper surface of the second wafer 520. In an embodiment, the first driver 461 and the second driver 462 may be positioned symmetrically with respect to the center of the second wafer 520.

After the first driver 461 and the second driver 462 contact the upper surface of the second wafer 520, the driver 460 may vacuum a space between the first driver 461 and the second wafer 520, and a space between the second driver 462 and the second wafer 520. As the space between the first driver 461 and the second wafer 520 and the space between the second driver 462 and the second wafer 520 become vacuum, the first driver 461 and the second driver 462 may come into tight contact with the second wafer 520.

Referring to FIG. 7, the first driver 461 may move in a vertical direction in a state in which the first driver 461 and the second driver 462 are in tight contact with the second wafer 520. In an embodiment, the first driver 461 may move at a constant speed. In a state in which the second driver 462 is in tight contact with the second wafer 520, the bonded wafers 510 and 520 may be separated from the edge according to the movement of only the first driver 461.

The sensor 470 may measure the time from the moment when the first driver 461 applies a force to the second wafer 520 until the bonded wafers 510 and 520 are completely separated and the force applied to the second wafer 520 during that time.

Referring to FIG. 8, after the moment when the bonded wafers 510 and 520 start being separated, the first driver 461 and the second driver 462 may together move in a vertical direction. In an embodiment, the first driver 461 and the second driver 462 may move at a constant speed. As the first driver 461 and the second driver 462 move in the vertical direction, the bonded wafers 510 and 520 are completely separated. As the bonded wafers 510 and 520 are completely separated, the sensor 470 may end the measurement.

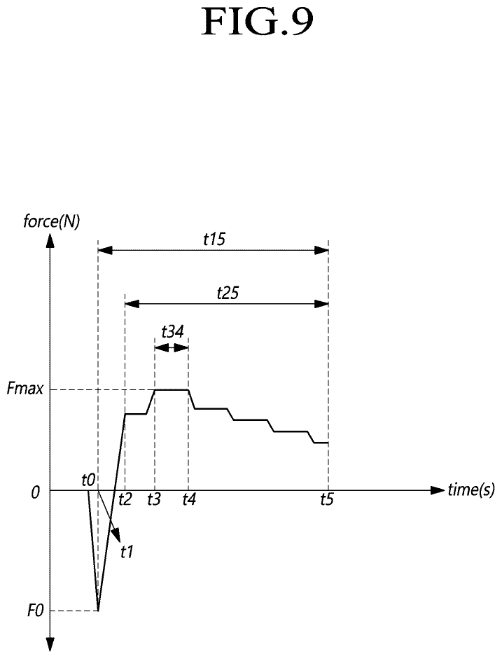

FIG. 9 is a view illustrating data measured when driving a bonding strength evaluation device according to embodiments of the present disclosure.

Referring to FIG. 9, changes over time in the force applied to the second wafer 520 while separating the bonded wafers 510 and 520 may be identified.

At timing t0, the first driver 461 and the second driver 462 contact the upper surface of the second wafer 520.

In the period of timing t0 to timing t1, the first driver 461 and the second driver 462 may be in tight contact with the upper surface of the second wafer 520. In an embodiment, a space between the first driver 461 and the second wafer 520 and a space between the second driver 462 and the second wafer 520 may be vacuumed in the period of timing t0 to timing t1. When a force is applied to one surface of the second wafer 520 using another method instead of a method of vacuuming the space between the first driver 461 and the second wafer 520, the period of timing t0 to timing t1 may be omitted.

At timing t1, the first driver 461 starts to move upward while pulling the second wafer 520. In an embodiment, the sensor 470 may measure the force applied to the second wafer 520 from timing t1 and the time during which the force is applied.

At timing t2, the bonded wafers 510 and 520 start being separated from one edge.

In the period of timing t2 to timing t3, there may be a period during which the force applied to the second wafer 520 increases. As described above, when the bonded wafers are separated from the edge, the bonding area increases toward the center of the wafer, so more and more force is needed to separate the bonded wafers. Therefore, the force applied to the second wafer 520 may increase after the bonded wafers are separated.

At timing t3, the bonded wafers 510 and 520 may be separated to the vicinity of the center of the wafer. The force applied to the second wafer 520 at timing t3 may be expressed as Fmax.

In the period of timing t3 to timing t4, the force applied to the second wafer 520 may be maintained. The force applied to the second wafer 520 in the period of timing t3 to timing t4 may be a force acting to separate the bonded wafers 510 and 520 near the center of the wafer.

At timing t4, the bonded wafers 510 and 520 may be separated by passing through the center of the wafer.

In the period of timing t4 to timing t5, the bonded wafers 510 and 520 are gradually separated to the other edge of the bonded wafers 510 and 520. As the separation proceeds, the bonding area gradually decreases, so that the bonded wafers 510 and 520 are easily separated, so that the force applied to the second wafer 520 gradually decreases.

At timing t5, the bonded wafers 510 and 520 are completely separated. As the bonded wafers 510 and 520 are completely separated, the force is no longer applied to the second wafer 520. As the bonded wafers 510 and 520 are completely separated, the sensor 470 ends the measurement.

The determination module 450 may determine the difference Fmax−F0 between the force Fmax applied to the second wafer 520 in the period of timing t3 to timing t4 and the force F0 applied to the second wafer 520 at timing t1 as the bonding strength of the bonded wafer 450.

Alternatively, the determination module 450 may determine the bonding strength based on the time t34 when the maximum force is applied to the second wafer 520, the time t15 taken from the moment when the force is applied to the second wafer 520 to the moment when the bonded wafers 510 and 520 are completely separated, or the time t25 taken from the moment when the bonded wafers 510 and 520 start being separated to the moment when the bonded wafers 510 and 520 are completely separated.

Alternatively, the determination module 450 may determine the bonding strength based on the product of the difference between the force Fmax applied to the second wafer 520 and the force F0 applied to the second wafer 520 at timing t1 and the time t34 when the maximum force is applied to the second wafer 520.

Alternatively, the determination module 450 may determine the bonding strength based on the separation distance between the bonded wafers 210 and 220, the distance of the area where the bonded wafers 210 and 220 are separated, or a combination thereof, at a time in the period t34 when the maximum force is applied to the second wafer 520

According to the above-described bonding strength evaluation method, bonding strength evaluation device, and driving method, the bonding strength may be determined by measuring the time required for separation while separating bonded wafers or the force acting on the wafer during separation.

Conventionally known bonding strength determination methods determine the bonding strength by measuring the crack length by applying cracks to the wafer or based thereupon, or determine the bonding strength based on the measurement of the length of separation caused by repeating the application and removal of force to the wafer several times.

However, all of the known conventional methods may cause stress and damage to the wafers and may not be used to measure the bonding strength of the wafer where the integrated circuits or memory cells are disposed. Further, the conventional methods lack consistency in measurement due to variations in the crack length of the wafer or separation length caused by, e.g., moisture or working conditions in the place where measurement is performed.

Embodiments of the present disclosure are capable of measuring the bonding strength by a debonding method without causing repeated stress or artificial cracks to the wafers, and are thus used to measure the bonding strength in wafers where integrated circuits and memory cells are disposed.

Further, as the force applied to the wafer or the time during which the force is applied relies only on the bonding strength of the bonded wafers, consistency in determination of the bonding strength may be secured even when the measurement conditions are varied, thus providing more accuracy in bonding strength evaluation.

According to embodiments of the present disclosure, the determination module 450 may determine the maximum force among the forces applied to one surface of the bonded wafers 210 and 220 as the bonding strength.

According to embodiments of the present disclosure, the determination module 450 may determine the bonding strength based on the time during which the maximum force among the forces applied to one surface of the bonded wafers 210 and 220 is maintained.

According to embodiments of the present disclosure, the determination module 450 may determine the bonding strength based on the time taken from the moment when a force is applied to the bonded wafers 210 and 220 to the moment when the bonded wafers 210 and 220 are completely separated.

According to embodiments of the present disclosure, the determination module 450 may determine the bonding strength based on the time taken from the moment when the bonded wafers 210 and 220 start being separated to the moment when the bonded wafers 210 and 220 are completely separated.

According to embodiments of the present disclosure, the determination module 450 may determine the bonding strength based on the product of the maximum force among the forces applied to one surface of the bonded wafers 210 and 220 and the time during which the maximum force is maintained.

The above-described embodiments are merely illustrative, and it will be appreciated by one of ordinary skill in the art various changes may be made thereto without departing from the scope of the present disclosure. Accordingly, the embodiments set forth herein are provided for illustrative purposes, but not to limit the scope of the present disclosure, and should be appreciated that the scope of the present disclosure is not limited by the embodiments. The scope of the present disclosure should be construed by the following claims, and all technical spirits within equivalents thereof should be interpreted to belong to the scope of the present disclosure. Furthermore, the embodiments may be combined to form additional embodiments.

What is claimed is:

1. A bonding strength evaluation method comprising:
preparing bonded wafers;
separating the bonded wafers by applying a force to one surface of the bonded wafers in a direction perpendicular to the one surface of the bonded wafers;
measuring at least one of the force applied to the one surface of the bonded wafers, a time during which the force is applied, a separation distance between the bonded wafers, and a length of an area where the bonded wafers are separated; and
determining a bonding strength based on at least one of the force, the time during which the force is applied, the separation distance between the bonded wafers, and the length of the area where the bonded wafers are separated.

2. The bonding strength evaluation method of claim 1,
wherein preparing the bonded wafers includes bonding a first wafer and a second wafer, and
wherein separating the bonded wafers includes applying the force to one surface of the second wafer in a state in which the first wafer is fixed to separate the first wafer and the second wafer.

3. The bonding strength evaluation method of claim 2, wherein separating the bonded wafers includes applying the force to the one surface of the second wafer from an edge of the one surface.

4. The bonding strength evaluation method of claim 1, wherein measuring at least one of the force includes measuring the force and the time, in a period from a moment when the force is applied to the bonded wafers to a moment when the bonded wafers are completely separated.

5. The bonding strength evaluation method of claim 1, wherein determining the bonding strength includes determining a maximum force among forces applied to the one surface of the bonded wafers as the bonding strength.

6. The bonding strength evaluation method of claim 1, wherein determining the bonding strength includes determining the bonding strength based on a time during which a maximum force among forces applied to the bonded wafers is maintained.

7. The bonding strength evaluation method of claim 1, wherein determining the bonding strength includes determining the bonding strength based on a time taken from a moment when the force is applied to the bonded wafers to a moment when the bonded wafers are completely separated.

8. The bonding strength evaluation method of claim 1, wherein determining the bonding strength includes determining the bonding strength based on a time taken from a moment when the bonded wafers start being separated to a moment when the bonded wafers are completely separated.

9. The bonding strength evaluation method of claim 1, wherein determining the bonding strength includes determining the bonding strength based on a product of a maximum force among forces applied to the one surface of the bonded wafers and a time during which the maximum force is maintained.

10. The bonding strength evaluation method of claim 1, wherein determining the bonding strength includes determining the bonding strength based on at least one of the separation distance between the bonded wafers when a maximum force among forces applied to the bonded wafers is applied to the one surface of the bonded wafers and the length of the area where the bonded wafers are separated when the maximum force is applied to the one surface of the bonded wafers.

11. The bonding strength evaluation method of claim 10, wherein determining the bonding strength includes determining the bonding strength based on a product of the separation distance between the bonded wafers when the maximum force is applied to the one surface of the bonded wafers and the length of the area where the bonded wafers are separated when the maximum force is applied to the one surface of the bonded wafers.

12. The bonding strength evaluation method of claim 1,
wherein preparing the bonded wafers includes bonding a first wafer and a second wafer, and
wherein the separation distance between the bonded wafers is a maximum distance from an edge of one surface of the second wafer to one surface of the first wafer.

13. The bonding strength evaluation method of claim 1, wherein the length of the area where the bonded wafers are separated is a maximum distance from an edge of one of the bonded wafers to an area where the bonded wafers are not separated.

14. A bonding strength evaluation device comprising:
a wafer holder configured to fix bonded wafers; and
a determination module configured to determine a bonding strength of the bonded wafers, wherein the determination module includes:
a driver configured to separate the bonded wafers by applying a force to the bonded wafers in a direction perpendicular to one surface of the bonded wafers; and
a sensor configured to measure at least one of the force applied to the one surface of the bonded wafers, a time during which the force is applied, a separation distance between the bonded wafers, and a length of an area where the bonded wafers are separated.

15. The bonding strength evaluation device of claim 14,
wherein the driver is configured to contact one surface of one wafer of the bonded wafers and pull the one wafer to separate the bonded wafers,
wherein the driver includes a first driver and a second driver contacting different positions of the one surface of the one wafer, and
wherein the first driver and the second driver independently apply the force to the one surface of the one wafer.

16. The bonding strength evaluation device of claim 15, wherein the first driver is configured to apply the force to the one surface of the one wafer before the bonded wafers are separated and, after a moment when the bonded wafers start being separated, the first driver and the second driver apply the force to the one surface of the one wafer.

17. The bonding strength evaluation device of claim 14, further comprising a blade configured to apply a force to a boundary of the bonded wafers to separate the bonded wafers.

18. The bonding strength evaluation device of claim 14, wherein the sensor is configured to measure the force applied to the one surface of the bonded wafers and the time during which the force is applied, in a period from a moment when the force is applied to the bonded wafers to a moment when the bonded wafers are completely separated.

19. The bonding strength evaluation device of claim 14, wherein the determination module is configured to determine the bonding strength based on at least one of the separation distance between the bonded wafers when a maximum force is applied to the one surface of the bonded wafers and the length of the area where the bonded wafers are separated when the maximum force is applied to the one surface of the bonded wafers.

20. A driving method of a bonding strength evaluation device, the driving method comprising:
fixing bonded wafers to a wafer holder; and
separating the bonded wafers by applying a force to one of the bonded wafers in a direction perpendicular to one surface of the one wafer while measuring at least one of the force applied to the one wafer, a time during which the force is applied, a separation distance between the bonded wafers, and a length of an area where the bonded wafers are separated, to determine a bonding strength.
